(19) United States
(12) Patent Application Publication
(10) Pub. No.: US 2025/0179350 A1
(43) Pub. Date: Jun. 5, 2025

(54) COMPOSITE MATERIAL, AND PREPARATION METHOD THEREFOR, AND LIGHT-EMITTING DEVICE

(71) Applicants: Guangdong Juhua Research Institute of Advanced Display, Guangzhou (CN); TCL Technology Group Corporation, Huizhou (CN)

(72) Inventor: Aozhen XIE, Guangzhou (CN)

(73) Assignees: Guangdong Juhua Research Institute of Advanced Display, Guangzhou (CN); TCL Technology Group Corporation, Huizhou (CN)

(21) Appl. No.: 18/969,328

(22) Filed: Dec. 5, 2024

(30) Foreign Application Priority Data
Dec. 5, 2023 (CN) 202311661894.4

(51) Int. Cl. C09K 11/02; B82Y 20/00; B82Y 40/00; C09K 11/08; C09K 11/56; C09K 11/70; C09K 11/88; H10K 50/115

(52) U.S. Cl. CPC C09K 11/025; C09K 11/0883; C09K 11/565; C09K 11/703; C09K 11/883; H10K 50/115; B82Y 20/00; B82Y 40/00

(57) ABSTRACT

Disclosed in the present disclosure are a composite material, and a preparation method therefor, and a light-emitting device, and the composite material includes first quantum dots and second quantum dots, each of the first quantum dots have N-type ligands thereon, and each of the second quantum dots have P-type ligands thereon.

This application claims priority to and the benefit of Chinese Patent Application No. 202311661894.4, filed on Dec. 5, 2023, the disclosure of which is incorporated herein by reference in its entirety.

### TECHNICAL FIELD

The present disclosure relates to the technical field of light-emitting devices, and in particular, to a composite material, and a preparation method therefor, and a light-emitting device.

### BACKGROUND

Quantum dot materials are widely used in photoelectric devices. The imbalance of carrier injection in photoelectric devices leads to leads to faster performance roll-off and generally shorter lifetime of devices.

### SUMMARY

Therefore, the present disclosure provides a composite material, and a preparation method therefor, and a light-emitting device.

In a first aspect, the present disclosure provides a composite material including:
first quantum dots, each of the first quantum dots having N-type ligands thereon; and
second quantum dots, each of the second quantum dots having P-type ligands thereon.

In some embodiments of the present disclosure, each of the first quantum dots includes a metal element M, and each of the N-type ligands is selected from a halide of the metal element M.

In some embodiments of the present disclosure, each of the N-type ligands includes one or more of zinc halide, cadmium halide, mercury halide, lead halide, tin halide, copper halide, silver halide, gallium halide and indium halide.

In some embodiments of the present disclosure, each of the N-type ligands includes one or more of zinc fluoride, zinc chloride, zinc bromide, zinc iodide, cadmium fluoride, cadmium chloride, cadmium bromide and cadmium iodide.

In some embodiments of the present disclosure, each of the P-type ligands is selected from any one or more of the compounds represented by the following formula I,

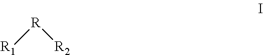

Wherein R₁ and R₂ are each independently selected from one of —H, —SH, —COOH, —NH₂, —OH, —NHR₃, —NR₄R₅, —PO₃H₂, —PO₃HR₆, —PO₃R₇R₈, —SO₃H and —SO₃R₉, but not all are H;

R is selected from one of a C₁-C₃₀ divalent aliphatic hydrocarbon group, a C₆-C₃₀ arylene group and a C₃-C₃₀ divalent heteroaryl group having heteroatoms selected from O, S, N and P;

R₃, R₄, R₅, R₆, R₇, R₈ and R₉ are selected from C₁-C₆ hydrocarbyl groups.

In some embodiments of the present disclosure, R in the P-type ligand is selected from one of a C₃-C₁₅ divalent aliphatic hydrocarbon group, a C₆-C₁₈ arylene group and a C₆-C₁₈ divalent heteroaryl group.

In some embodiments of the present disclosure, each of the P-type ligands includes one or more of propylene glycol, butanediol, pentanediol, hexanediol, 2-mercaptoethanol, 2-mercaptophenol, 4-hydroxythiophene, 2-aminoethanethiol, 3-mercaptophenol, 4-hydroxythiophenol, 2-aminothiophenol, 3-aminothiophenol, 4-aminothiophenol, oxalic acid, malonic acid, succinic acid, adipic acid, and maleic acid.

In some embodiments of the present disclosure, a molar ratio of the first quantum dots to the second quantum dots ranges from 0.25 to 25.

In some embodiments of the present disclosure, an average particle size of the first quantum dots ranges from 7 nm to 12 nm.

In some embodiments of the present disclosure, an average particle size of the second quantum dots ranges from 7 nm to 12 nm.

In some embodiments of the present disclosure, the first quantum dots and the second quantum dots are independently selected from one or more of a single structure quantum dot, a core-shell structure quantum dot, and a perovskite-type semiconductor material, wherein a material of the single structure quantum dot, a core material of the core-shell structure quantum dot and a shell material of the core-shell structure quantum dot are respectively selected from at least one of a Group II-VI compound, a Group IV-VI compound, a Group III-V compound, and a Group I-III-VI compound, the Group II-VI compound is selected from one or more of CdS, CdSe, CdTe, ZnS, ZnSe, ZnTe, ZnO, CdSeS, ZnSeS, ZnSeTe, ZnSTe, and CdZnSeS, the Group III-V compound is selected from GaN, GaP, GaAs, GaSb, AlN, AIP, AIAs, AlSb, InN, InP, GaNP, AlNP, AlNAs, AlNSb, AlPAs, AlPSb, InNP, GaAlNP, GaAlNAs, GaInNP, and InAlNP, the Group I-III-VI compound is selected from one or more of CuInS₂, CuInSe₂, and AgInS₂.

In some embodiments of the present disclosure, a material of each of the first quantum dots and a material of each of the second quantum dots are the same.

In a second aspect, the present disclosure provides a method of preparing a composite material, including:
providing first quantum dots and second quantum dots, wherein each of the first quantum dots has N-type ligands thereon, and each of the second quantum dots has P-type ligands thereon;
mixing a first quantum dot solution having the N-type ligands and a second quantum dot solution having the P-type ligands according to a preset ratio to obtain a quantum dot mixed solution, and removing a solvent in the quantum dot mixed solution to obtain the composite material.

In some embodiments of the present disclosure, the step of providing first quantum dots and second quantum dots includes:
providing an initial quantum dot solution, wherein the initial quantum dot solution includes quantum dots and initial ligands bonded to the surface of the quantum dots;
dropwise adding a solution having the N-type ligands to the initial quantum dot solution to obtain a first ligand replacement precursor solution, and performing ligand exchange between the N-type ligands and the initial ligands in the first ligand replacement precursor solution by a solution ligand exchange method to obtain the first quantum dots, wherein each of the first quantum dots has the N-type ligands thereon; and,
dropwise adding a solution having the P-type ligands to the first quantum dot solution to obtain a second ligand replacement precursor solution, and performing ligand exchange between the P-type ligands and the N-type ligands in the second ligand replacement precursor solution by the solution ligand exchange method to obtain the second quantum dots, wherein each of the second quantum dots has the P-type ligands thereon.

In some embodiments of the present disclosure, each of the P-type ligands is selected from any one or more of the compounds represented by the following formula I,

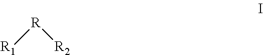

Wherein R₁ and R₂ are each independently selected from one of —H, —SH, —COOH, —NH₂, —OH, —NHR₃, —NR₄R₅, —PO₃H₂, —PO₃HR₆, —PO₃R₇R₈, —SO₃H and —SO₃R₉, but not all are H; R is selected from one of a C₁-C₃₀ divalent aliphatic hydrocarbon group, a C₆-C₃₀ arylene group and a C₃-C₃₀ divalent heteroaryl group having heteroatoms selected from O, S, N and P; R₃, R₄, R₅, R₆, R₇, R₈ and R₉ are selected from C₁-C₆ hydrocarbyl groups.

In some embodiments of the present disclosure, each of the first quantum dots includes a metal element M, and the N-type ligand is selected from a halide of the metal element M.

In a third aspect, the present disclosure provides a light-emitting device including a light-emitting layer, wherein the light-emitting layer is made of a composite material including first quantum dots and second quantum dots;

each of the first quantum dots have N-type ligands thereon, and each of the second quantum dots have P-type ligands thereon.

In some embodiments of the present disclosure, each of the first quantum dots includes a metal element M, and each of the N-type ligands is selected from a halide of the metal element M;
each of the P-type ligands is selected from any one or more of the compounds represented by the following formula I,

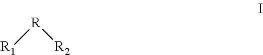

wherein R₁ and R₂ are each independently selected from one of —H, —SH, —COOH, —NH₂, —OH, —NHR₃, —NR₄R₅, —PO₃H₂, —PO₃HR₆, —PO₃R₇R₈, —SO₃H and —SO₃R₉, but not all are H; R is selected from one of a C₁-C₃₀ divalent aliphatic hydrocarbon group, a C₆-C₃₀ arylene group and a C₃-C₃₀ divalent heteroaryl group having heteroatoms selected from O, S, N and P; R₃, R₄, R₅, R₆, R₇, R₈ and R₉ are selected from C₁-C₆ hydrocarbyl groups.

In some embodiments of the present disclosure, each of the N-type ligands includes one or more of zinc fluoride, zinc chloride, zinc bromide, zinc iodide, cadmium fluoride, cadmium chloride, cadmium bromide and cadmium iodide; each of the P-type ligands includes one or more of propylene glycol, butanediol, pentanediol, hexanediol, 2-mercaptoethanol, 2-mercaptophenol, 4-hydroxythiophene, 2-aminoethanethiol, 3-mercaptophenol, 4-hydroxythiophenol, 2-aminothiophenol, 3-aminothiophenol, 4-aminothiophenol, oxalic acid, malonic acid, succinic acid, adipic acid, maleic acid.

In some embodiments of the present disclosure, a molar ratio of the first quantum dots to the second quantum dots ranges from 0.25 to 25.

### BRIEF DESCRIPTION OF THE DRAWINGS

In order to more clearly explain the technical solutions in the embodiments of the present disclosure, the figures to be used in the description of the embodiments are briefly described below. It is apparent that the figures in the following description are merely some embodiments of the present disclosure. For those skilled in the art, without involving any creative effort, other figures may be obtained based on these figures.

FIG. 1 is a schematic diagram of an energy level structure of a light-emitting device according to an embodiment of the present disclosure.

FIG. 2 is a schematic diagram of the energy level structure of the light-emitting device according to another embodiment of the present disclosure.

FIG. 3 is a schematic diagram of the light-emitting device according to an embodiment of the present disclosure.

FIG. 4 is a flow chart of a method for preparing a composite material according to an embodiment of the present disclosure.

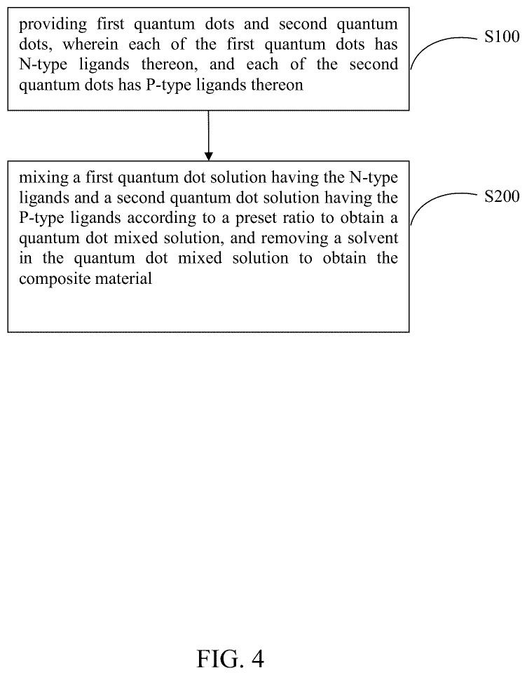

### DETAILED DESCRIPTION

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure.

In the present disclosure, the word “exemplary” is used to mean “serving as an example, illustration, or illustration.” Any embodiment described as “exemplary” in the present disclosure is not necessarily to be construed as being more preferred or superior to other embodiments. In order to enable any person skilled in the art to carry out and use the present invention, the following description is given. In the following description, details are set forth for purposes of explanation. It should be understood that one of ordinary skill in the art will recognize that the present invention can be practiced without using these specific details. In other examples, well-known structures and processes will not be elaborated in order to avoid obscuring the description of the invention with unnecessary details. Accordingly, the present invention is not intended to be limited to the illustrated embodiments, but to be accorded the widest scope consistent with the principles and features disclosed herein.

Furthermore, the terms “first” and “second” are for descriptive purposes only, and are not to be understood as indicating or implicitly indicating relative importance or the number of technical features indicated. Thus, features defined as “first”, “second” may explicitly or implicitly include one or more of the features. In the description of the present invention, “a plurality” means two or more unless specifically defined otherwise.

An embodiment of the present disclosure provides a quantum dot light-emitting device (hereinafter referred to as a light-emitting device), and the light-emitting device in the present disclosure has a long lifetime.

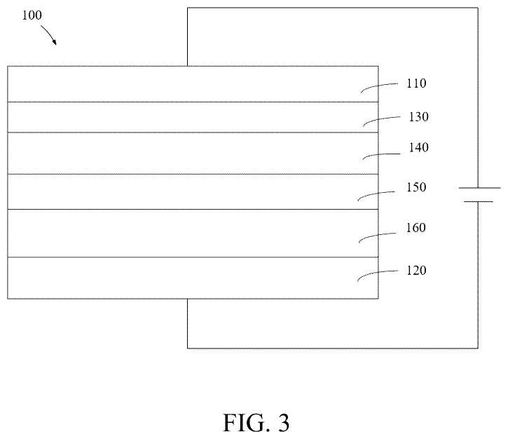

Referring to FIG. 3, FIG. 3 is a schematic diagram of the light-emitting device according to an embodiment of the present disclosure. The light emitting device 100 includes a first electrode 110 and a second electrode 120 disposed opposite each other. The first electrode 110 and the second electrode 120 are connected to a power supply so that the power supply supplies power to the light emitting device 100.

Specifically, in an embodiment of the present disclosure, the first electrode 110 is an anode, and the second electrode 120 is a cathode. Of course, in other embodiments of the present disclosure, the first electrode 110 may be the cathode and the second electrode 120 may be the anode, and the present disclosure does not limit this.

For example, the first electrode 110 may be selected from, but is not limited to, a doped metal oxide particle electrode, a composite electrode of metal and metal oxide, a graphene electrode, a carbon nanotube electrode, a metal electrode or an alloy electrode. A material of the doped metal oxide particle electrode is selected from one or more of indium doped tin oxide, fluorine doped tin oxide, antimony doped tin oxide, aluminum doped zinc oxide, gallium doped zinc oxide, indium doped zinc oxide, magnesium doped zinc oxide and aluminum doped magnesium oxide. The composite electrode of metal and metal oxide is selected from one or more of AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS. A material of the metal electrode is selected from one or more of Ag, Al, Cu, Mo, Au, Pt, Si, Ca, Mg and Ba. Further, a thickness of the first electrode 110 ranges from 20 nm to 200 nm.

For example, the second electrode 120 may be selected from, but is not limited to, a doped metal oxide particle electrode, a composite electrode of metal and metal oxide, a graphene electrode, a carbon nanotube electrode, a metal electrode or an alloy electrode. A material of the doped metal oxide particle electrode is selected from one or more of indium doped tin oxide, fluorine doped tin oxide, antimony doped tin oxide, aluminum doped zinc oxide, gallium doped zinc oxide, indium doped zinc oxide, magnesium doped zinc oxide and aluminum doped magnesium oxide. The composite electrode of metal and metal oxide is selected from one or more of AZO/Ag/AZO, AZO/AI/AZO, ITO/Ag/ITO, ITO/AI/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS. A material of the metal electrode is selected from one or more of Ag, Al, Cu, Mo, Au, Pt, Si, Ca, Mg and Ba. Further, a thickness of the second electrode 120 ranges from 20 nm to 200 nm.

It should be noted that a method of preparing the first electrode 110 and the second electrode 120 may be a method known in the technical field and the present disclosure will not further explain the method herein.

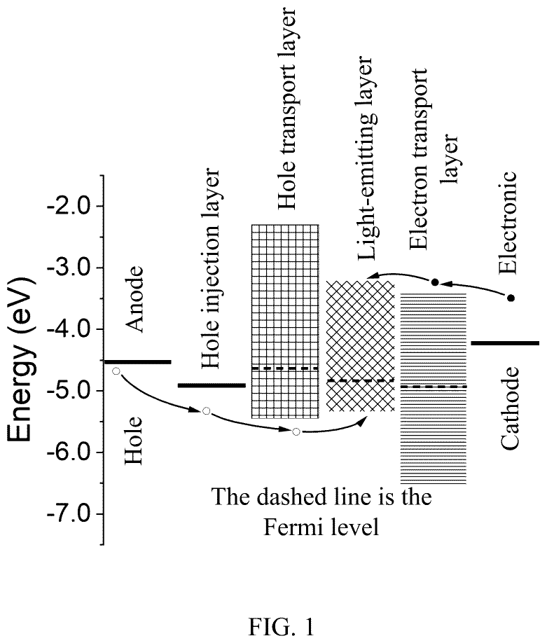

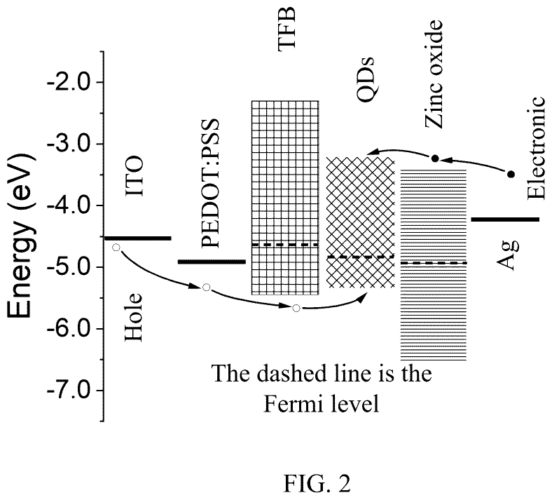

Referring to FIGS. 1 and 2, FIG. 1 is a schematic diagram of an energy level structure of a light-emitting device according to an embodiment of the present disclosure, and FIG. 2 is a schematic diagram of the energy level structure of the light-emitting device according to another embodiment of the present disclosure. When the light-emitting device is electrically connected to the power supply, under the action of an electric field, the holes generated by the anode and the electrons generated by the cathode move. When the two meet in the light-emitting layer, energy excitons are generated, thus exciting the light-emitting molecules to finally generate visible light.

It should be noted that, in the prior art, the electron transport ability is strong and the hole transport ability is poor, so that the carrier injection is imbalance, and thus, the performance roll-off of the light-emitting device occurs quickly and the lifetime of the device is usually short.

In view of the problems in the prior art that carrier injection imbalance leads to faster performance roll-off and generally shorter lifetime of light-emitting devices, the present disclosure provides a composite material including first quantum dots and second quantum dots. Each of the first quantum dots have N-type ligands thereon, and each of the second quantum dots have P-type ligands thereon. Exemplarily, the composite material is used to prepare a light-emitting layer 150 of a light-emitting device, that is, the light-emitting layer 150 includes compounded first quantum dots and second quantum dots. In the composite material provided by the present disclosure, the first quantum dots and the second quantum dots are compounded, so that when the composite material is used for preparing an light-emitting device, the carrier injection balance of the light-emitting device can be improved, and the service life of the light-emitting device can be improved. As shown in FIG. 2, taking a light-emitting device in which the hole transport layer is made of TFB and the electron transport layer is made of zinc oxide nanoparticles as an example, the composite material can be obtained by compounding the first quantum dots and the second quantum dots, and the Fermi level of the composite material is between TFB and zinc oxide nanoparticles. when the light-emitting layer of the light-emitting device is prepared by using the composite material, the potential barrier caused by band bending in the light-emitting device can be minimized, thereby improving the carrier injection balance of the light-emitting device and the lifetime of the light-emitting device. The first quantum dots and the second quantum dots compounded in the present disclosure refer to a mixture obtained by mixing the first quantum dots and the second quantum dots at a certain ratio. That is, the light-emitting layer includes the first quantum dots and the second quantum dots that are substantially uniformly distributed. Since the energy levels of the electron transport layer prepared from different materials or the hole transport layer prepared from different materials are greatly different, a molar ratio of the first quantum dots to the second quantum dots in the light-emitting layer of the present disclosure needs to be determined according to a specifically selected electron transport layer material, a specifically selected hole transport layer material, a specifically selected first quantum dot, and a specifically selected second quantum dot. Preferably, the molar ratio of the first quantum dots to the second quantum dots ranges from 0.25 to 25, and exemplarily, the molar ratio of the first quantum dots to the second quantum dots is 0.25, or 0.35, or 0.4, or 0.5, or 0.7, or 0.9, or 1.0, or 1.1, or 1.5, or 2.0, or 3.0, or 3.5, or 4.0, or 5.0, or 6.0, or 8.0, or 11.0, or 13.0, or 15.0, or 18.0, or 20.0, or 25.0. The inventors have found through experiments that the molar ratio of the first quantum dots to the second quantum dots in the quantum dot light-emitting layer is 0.25 to 25, the light-emitting layer may match the hole transport layer and the electron transport layer of different energy levels, and the obtained light-emitting device has relatively stable performance and long lifetime.

In some embodiments of the present disclosure, an average particle size of the first quantum dots ranges from 7 nm to 12 nm, and an average particle size of the second quantum dots ranges from 7 nm to 12 nm. Exemplarily, the first quantum dots have an average particle size of 7 nm, or 8 nm, or 9 nm, or 10 nm, or 11 nm, or 12 nm. The second quantum dots have an average particle size of 7 nm, or 8 nm, or 9 nm, or 10 nm, or 11 nm, or 12 nm.

In some embodiments of the present disclosure, the hole transport layer is made of TFB, the electron transport layer is made of zinc oxide nanoparticles, and the molar ratio of the first quantum dots to the second quantum dots ranges from 0.25 to 3. Preferably, the molar ratio of the first quantum dots to the second quantum dots ranges from 0.4 to 2.0, and the lifetime of the obtained light-emitting device is improved by more than 50%. The molar ratio of the first quantum dots to the second quantum dots is about 1.0, and the lifetime of the obtained light-emitting device is doubled.

In some embodiments of the present disclosure, the hole transport layer is made of poly (9-vinylcarbazole), the electron transport layer is made of Mg-doped zinc oxide nanoparticles, and the molar ratio of the first quantum dots to the second quantum dots ranges from 2.0 to 25.0. Preferably, the molar ratio of the first quantum dots to the second quantum dots ranges from 3.5 to 20.0, and the lifetime of the obtained light-emitting device is improved by more than 50%.

In some embodiments of the present disclosure, each of the first quantum dots includes a metal element M, and each of the N-type ligands is selected from a halide of the metal element M. For example, each of the N-type ligands includes one or more of zinc fluoride, zinc chloride, zinc bromide, zinc iodide, cadmium fluoride, cadmium chloride, cadmium bromide and cadmium iodide. Exemplarily, a first quantum dot is a CdSe quantum dot, and the N-type ligands may be one or more of cadmium chloride, cadmium iodide, and cadmium fluoride. For another example, the first quantum dot is ZnSe, and the N-type ligands may be one or more of zinc chloride, zinc iodide, and zinc fluoride. This structure may avoid introducing metal impurities into the light-emitting layer, and is beneficial to improving the control accuracy of the light-emitting layer. Of course, in other embodiments of the present disclosure, a metal element in each of the N-type ligands may also be different from a metal element in the first quantum dot, for example, the first quantum dot is a CdSe quantum dot, and the N-type ligands may be one or more of zinc chloride, zinc iodide, and zinc fluoride.

In some embodiments of the present disclosure, a material of each of the first quantum dots and a material of each of the second quantum dots are the same. In the present disclosure, a material of a quantum dot refers to a material of the quantum dot that is not bonded to the ligands, that is, the material of the quantum dot does not include the ligands bound to the surface of the quantum dot. Taking a CdSe quantum dot as an example, the material of the first quantum dot is the same as the material of a second quantum dot, that is, the material of the first quantum dot is CdSe, and the material of the second quantum dot is CdSe. Specifically, in this embodiment, the first quantum dot includes the CdSe quantum dot (that is, the first quantum dot) and the N-type ligands bonded to the surface of the CdSe quantum dot. The second quantum dot includes the CdSe quantum dot (that is, the second quantum dot) and the P-type ligands bonded to the surface of the CdSe quantum dot. Taking a ZnSe quantum dot as an example, the material of the first quantum dot and the material of the second quantum dot are both ZnSe, and specifically, in this embodiment, the first quantum dot includes the ZnSe quantum dot (that is, the first quantum dot) and the N-type ligands bonded to the surface of the ZnSe quantum dot. The second quantum dot includes the ZnSe quantum dot (that is, the second quantum dot) and the P-type ligands bonded to the surface of the ZnSe quantum dot. For another example, the first quantum dot is CdSeS and the second quantum dot is CdSeS. In this embodiment, by providing the first quantum dot and the second quantum dot to be the same, it is possible to further avoid introducing light-emitting impurities into the light-emitting layer, and it is beneficial to improve the control accuracy of the light-emitting device. Of course, in other embodiments of the present disclosure, the first quantum dot and the second quantum dot may be different, and no further limitation is made herein.

In some embodiments of the present disclosure, each of the P-type ligands is an organic compound whose structural formula is as shown in Formula I;

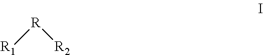

wherein R₁ and R₂ are each independently selected from one of —H, —SH, —COOH, —NH₂, —OH, —NHR₃, —NR₄R₅, —PO₃H₂, —PO₃HR₆, —PO₃R₇R₈, —SO₃H and —SO₃R₉, but not all are H; R is selected from one of a C₁-C₃₀ divalent aliphatic hydrocarbon group, a C₆-C₃₀ arylene group and a C₃-C₃₀ divalent heteroaryl group; further R is selected from one of a C₁-Cis divalent aliphatic hydrocarbon group, a C₆-C₁₈ arylene group and a C₆-C₁₈ divalent heteroaryl group; still further R is selected from one of a C₂-C₁₀ divalent aliphatic hydrocarbon group, a C₆-C₁₈ arylene group and a C₆-C₁₈ divalent heteroaryl group; still further R is selected from one of a C₂-C₆ divalent aliphatic hydrocarbon group, a C₆-C₁₀ arylene group and a C₆-C₁₀ divalent heteroaryl group. Heteroatoms of the heteroaryl group are selected from O, S, N, and P. R₃, R₄, R₅, R₆, R₇, R₈ and R₉ are selected from C₁-C₆ hydrocarbyl groups, which may be a C₁-C₆ alkyl group, a C₁-C₆ alkenyl group, a C₁-C₆ alkynyl group, or a phenyl group.

The divalent aliphatic hydrocarbon group refers to a portion remaining after two hydrogen atoms are removed from the same carbon atom or two different carbon atoms in the aliphatic hydrocarbon compound, and exemplarily, the divalent aliphatic hydrocarbon group includes an alkylene group, an alkenylene group, and an alkynylene group. The alkylene group includes, but is not limited to, CH₂, CH(CH₃), C(CH₃)₂, CH₂CH₂, CH₂CH(CH₃), CH₂C(CH₃)₂, CH₂CH₂CH₂ and CH₂CH₂CH₂CH₂. The alkenylene group includes, but is not limited to, CH═CH, CH═CHCH₂, and CH₂CH═CH. The alkynylene group includes, but is not limited to, C≡C, CH₂C≡C and CH₂CH₂CH₂C≡C.

In some embodiments of the present disclosure, each of the P-type ligands is a multifunctional ligand, that is, each of the P-type ligands includes at least two of —SH, —COOH, —NH₂, —OH, —NHR₃, —NR₄R₅, —PO₃H₂, —PO₃HR₆, —PO₃R₇R₈, —SO₃H and —SO₃R₉. For example, HO—R—OH, NH₂—R—OH, NH₂—R—SH, HOOC—R—COOH, HO—R—SH, NH₂—R—SH and the like. Exemplarily, each of the P-type ligands includes, but is not limited to, propylene glycol, butanediol, pentanediol, hexanediol, 2-mercaptoethanol, 2-mercaptophenol, 4-hydroxythiophene, 2-aminoethanethiol, 3-mercaptophenol, 4-hydroxythiophenol, 2-aminothiophenol, 3-aminothiophenol, 4-aminothiophenol, oxalic acid, malonic acid, succinic acid, adipic acid, and maleic acid.

In some embodiments of the present disclosure, the first quantum dots and the second quantum dots are independently selected from one or more of a single structure quantum dot, a core-shell structure quantum dot, and a perovskite-type semiconductor material, wherein a material of the single structure quantum dot, a core material of the core-shell structure quantum dot and a shell material of the core-shell structure quantum dot are respectively selected from at least one of a Group II-VI compound, a Group IV-VI compound, a Group III-V compound, and a Group I-III-VI compound, the Group II-VI compound is selected from one or more of CdS, CdSe, CdTe, ZnS, ZnSe, ZnTe, ZnO, CdSeS, ZnSeS, ZnSeTe, ZnSTe, and CdZnSeS, the Group III-V compound is selected from GaN, GaP, GaAs, GaSb, AlN, AIP, AlAs, AlSb, InN, InP, GaNP, AlNP, AlNAs, AlNSb, AlPAs, AlPSb, InNP, GaAlNP, GaAlNAs, GaInNP, and InAlNP, the Group I-III-VI compound is selected from one or more of CuInS₂, CuInSe₂, and AgInS₂.

In some embodiments of the present disclosure, functional layers further include a hole injection layer 130. A material of the hole injection layer 130 is selected from at least one of Dipyrazino[2,3-f:2′,3′-h]quinoxaline-2,3,6,7,10,11-hexacarbonitrile, PEDOT, PEDOT:PSS, derivatives of PEDOT:PSS incorporated s-MoO₃, 4,4′,4″-Tris(N-3-methylphenyl-N-phenylamino)triphenylamine, Copper (II) phthalocyanine, nickel oxide, molybdenum oxide, tungsten oxide, vanadium oxide, molybdenum sulfide, tungsten sulfide, and copper oxide.

In some embodiments of the present disclosure, a thickness of the hole injection layer 130 ranges from 10 nm to 50 nm.

In some embodiments of the present disclosure, the functional layers further include a hole transport layer 140. A material of the hole transport layer 140 is selected from one or more of 4,4′-Bis(N-carbazolyl)-1,1′-biphenyl (CBP), N,N′-Bis(1-naphthalenyl)-N,N′-bisphenyl-(1,1′-biphenyl)-4,4′-diamine, N,N′-bis(3-methylphenyl)-N,N′-diphenyl-benzidine, N,N′-bis(4-(N,N′-diphenylamino)phenyl)-N,N′-diphenylbenzidine, 4,4′,4″-Tri-9-carbazolyltriphenylaMine, 4,4′,4″-Tris(N-3-methylphenyl-N-phenylamino)triphenylamine, Poly[(9,9-dioctylfluorenyl-2,7-diyl)-co-(4,4′-(N-(4-sec-butylphenyl) diphenylamine)], Poly[N,N′-bis(4-butylphenyl)-N,N′-bis(phenyl)-benzi, polyaniline, polypyrrole, Poly[2-methoxy-5-(2-ethylhexyloxy)-1,4-phenylenevinylene] and Poly[2-methoxy-5-(3′,7′-dimethyloctyloxy)-1,4-phenylenevinylene], Copper (II) phthalocyanine, tertiary aromatic amine, polynuclear aromatic tertiary amine, 4,4′-Bis(N-carbazolyl)-1,1′-biphenyl, N,N,N′,N′-Tetraphenylbenzidine, PEDOT:PSS and its derivatives, poly (N-vinyl carbazole) (PVK) and its derivatives, Poly(methyl methacrylate) and its derivatives, Poly(9,9-dioctylfluorene) and its derivatives, poly (spirofluorene) and its derivatives, N,N′-bis (naphthalen-1-yl)-N,N′-bis(phenyl)benzidine, piro[2H-1-benzopyran-2,2′-[2H]indole], 1′,3′-dihydro-1′,3′,3′-trimethyl-6-nitro-, doped graphene, undoped graphene, C₆₀, doped or undoped NiO, doped or undoped MoO₃, doped or undoped WO₃, doped or undoped V₂O₅, doped or undoped P-type gallium nitride, doped or undoped CrO₃, doped or undoped CuO.

In some embodiments of the present disclosure, a thickness of the hole transport layer ranges from 15 nm to 40 nm.

In some embodiments of the present disclosure, the functional layers further include an electron transport layer 160. A material of the electron transport layer is selected from at least one of a metal oxide, a doped metal oxide, a Group II-VI semiconductor material, a Group III-V semiconductor material, and a Group I-III-VI semiconductor material, and the metal oxide is selected from at least one of ZnO, BaO, TiO₂, and SnO₂; a metal oxide of the doped metal oxide is selected from at least one of ZnO, TiO₂, and SnO₂, a doping element of the doped metal oxide is selected from at least one of Al, Mg, Li, In, and Ga, and the Group II-VI semiconductor material is selected from at least one of ZnS, ZnSe, and CdS; the Group III-V semiconductor material is selected from at least one of InP and GaP; the Group I-III-VI semiconductor material is selected from at least one of CuInS and CuGaS.

The present disclosure also provides a method for preparing a composite material, the method includes steps S100 and S200.

In step S100, first quantum dots and second quantum dots are provided. Wherein each of the first quantum dots has N-type ligands thereon, and each of the second quantum dots has P-type ligands thereon.

Specifically, in some embodiments of the present disclosure, initial quantum dots may be synthesized first, wherein an initial quantum dot solution includes quantum dots and initial ligands bonded to the surface of a quantum dot, and then a first quantum dot solution and a second quantum dot solution may be obtained by a ligand replacement process. Wherein the step of preparing the first quantum dot solution includes dropwise adding a solution having the N-type ligands to the initial quantum dot solution to obtain a first ligand displacement precursor solution, and performing ligand exchange between the N-type ligands and the initial ligands in the first ligand replacement precursor solution by a solution ligand exchange method to obtain the first quantum dots having the N-type ligands thereon. Wherein the step of preparing a second quantum dot solution includes dropwise adding a solution having the P-type ligands to the first quantum dot solution to obtain a second ligand replacement precursor solution, and performing ligand exchange between the P-type ligands and the N-type ligands in the second ligand replacement precursor solution by the solution ligand exchange method to obtain the second quantum dots having the P-type ligands thereon. It should be noted that the specific conditions of the ligand replacement process do not belong to the main improvement points of the present disclosure, and are not limited herein.

In step S200, the first quantum dot solution having the N-type ligands and the second quantum dot solution having the P-type ligands are mixed at a preset ratio to obtain a quantum dot mixed solution, and a solvent in the quantum dot mixed solution is removed to obtain the composite material. Exemplarily, the molar ratio of the first quantum dots to the second quantum dots is from 0.25 to 25. Removing the solvent in the quantum dot mixed solution by heating under vacuum conditions to obtain the composite material. It may be understood that a mixed solution in the present disclosure may be a mixed solution directly composed of the first quantum dots, the second quantum dots, and the solvent. Alternatively, the first quantum dot solution and the second quantum dot solution may be prepared first, and then the first quantum dot solution and the second quantum dot solution may be mixed according to a preset configuration to obtain the mixed solution.

Hereinafter, the preparation of CdSe quantum dots (that is, first quantum dots) having cadmium iodide ligands and cadmium bromide ligands and CdSe quantum dots (that is, second quantum dots) having 2-aminoethanethiol ligands will be described as examples. The specific preparation steps are shown in the following steps S110 to S150.

In step S110, CdSe quantum dots having myristanoic acid ligands were prepared.

34 mg of cadmium oxide, 161 mg of myristic acid, and 16 mL of octadec-1-ene were added to a 100 mL three-necked flask, and the temperature was raised to 200° C. under an argon atmosphere to completely dissolve the cadmium oxide, and then naturally cooled to room temperature to obtain a cadmium solution. Next, 15 mg of selenium powder was added to the cadmium solution, and argon gas was bubbled through for 20 minutes, and then the bubbling was stopped, but the reaction system was kept in the argon atmosphere. The reaction system was then warmed to 200° C. for 1.5 hours and then naturally cooled to room temperature. Finally, CdSe quantum dots with myristic acid ligands were precipitated by precipitation centrifugation.

In step S120, a solution of first quantum dots (cadmium iodide and cadmium bromide as ligands) was prepared.

An appropriate amount of CdSe quantum dots (myristic acid as ligands) obtained in step S110 was dissolved in n-octane to obtain a CdSe quantum dot n-octane solution with a concentration of 7 mg/mL. A molar concentration of CdSe quantum dots in n-octane solution may be determined by ultraviolet-visible absorption spectroscopy.

192.3 mg of cadmium iodide, 30.2 mg of cadmium bromide and 25.6 mg of ammonium acetate were dissolved in 5 mL of methylformamide to prepare a first ligand displacement precursor solution. Then, 5 mL of the CdSe quantum dot n-octane solution was uniformly mixed with the first ligand displacement precursor solution until all quantum dots were transferred to the first ligand displacement precursor solution, then the n-octane solution was poured out, and then the n-octane solvent was mixed and washed with the first ligand displacement precursor solution three times. Then adding toluene to the first ligand displacement precursor solution to precipitate to obtain CdSe quantum dots, and then vacuum drying the CdSe quantum dots to obtain the first quantum dots (cadmium iodide and cadmium bromide as ligands).

A appropriate amount of first quantum dots (cadmium iodide and cadmium bromide as ligands) is dispersed in n-butylamine solvent to obtain a first quantum dot solution. A molar concentration of the first quantum dot solution may be determined by ultraviolet-visible absorption spectroscopy.

In step S130, a solution of second quantum dots (2-aminoethanethiol as ligands) was prepared.

Slowly add 0.1 mol/L 2-aminoethanethiol-DMF solution dropwise to the first quantum dot solution and stir for 10 minutes to mix thoroughly to obtain a mixed solution. Then pour the mixed solution into toluene to precipitate to obtain a precipitate, and the precipitate is washed and purified by DMF-toluene, and then dried in a vacuum drying oven to obtain a second quantum dot powder.

The second quantum dot powder was dispersed in n-butylamine to obtain a second quantum dot (2-aminoethanethiol as ligand) solution. A molar concentration of the second quantum dot solution may be determined by ultraviolet-visible absorption spectroscopy.

It should be noted that the specific methods for preparing the initial quantum dots, the first quantum dot solution, and the second quantum dot solution do not belong to the main improvement points of the present disclosure, and those skilled in the technical field can select an appropriate quantum dot preparation method according to their needs, and are not limited herein.

In step S140, the first quantum dot solution and the second quantum dot solution were mixed according to a preset ratio to obtain a mixed quantum dot solution. After the mixed quantum dot solution is obtained, the solvent in the mixed quantum dot solution was removed to obtain the composite material.

Exemplarily, the molar concentration of the first quantum dot solution is 5 mg/mL. The molar concentration of the second quantum dot solution was 5 mg/mL. 5 mL of the first quantum dot solution and 5 mL of the second quantum dot solution are uniformly mixed to obtain a mixed quantum dot solution having a molar ratio of 1:1 between the first quantum dot and the second quantum dot.

In step S150, the mixed quantum dot solution was applied on a substrate to obtain a quantum dot light-emitting layer.

Exemplarily, the substrate is a glass substrate. The mixed quantum dot solution was applied on the substrate by a spin coating process to obtain a wet film, and the wet film was dried to obtain the quantum dot light-emitting layer. It should be noted that the preparation of the quantum dot light-emitting layer from the mixed quantum dot solution does not belong to the main improvement point of the present disclosure, and those skilled in the technical field may select an appropriate preparation method according to their needs, and is not limited herein.

Another aspect of the present disclosure provides a display device including a substrate (i.e., a substrate substrate) and a light emitting device disposed on the substrate. The display device having the light-emitting device also has the excellent performance of the light-emitting device of the present disclosure, and the description thereof will not be repeated here.

### Quantum Dot Preparation Example 1

Step 1 Preparation of CdSe Quantum Dots with Myristic Acid Ligands.

34 mg of cadmium oxide, 161 mg of myristic acid, and 16 mL of octadec-1-ene were added to a 100 mL three-necked flask, and the temperature was raised to 200° C. under an argon atmosphere to completely dissolve the cadmium oxide, and then naturally cooled to room temperature to obtain a cadmium solution. Next, 15 mg of selenium powder was added to the cadmium solution, and argon gas was bubbled through for 20 minutes, and then the bubbling was stopped, but the reaction system was kept in the argon atmosphere. The reaction system was then warmed to 200° C. for 1.5 hours and then naturally cooled to room temperature. Finally, CdSe quantum dots with myristic acid ligands were precipitated by precipitation centrifugation.

Step 2 Preparation of CdSe Quantum Dots with Cadmium Iodide Ligands and Cadmium Bromide as Ligands.

An appropriate amount of CdSe quantum dots with myristic acid ligands obtained in step 1 was dissolved in n-octane to obtain a CdSe quantum dot n-octane solution with a concentration of 7 mg/mL.

192.3 mg of cadmium iodide, 30.2 mg of cadmium bromide and 25.6 mg of ammonium acetate were dissolved in 5 mL of methylformamide to prepare a first ligand displacement precursor solution. Then, 5 mL of the CdSe quantum dot n-octane solution was uniformly mixed with the first ligand displacement precursor solution until all quantum dots were transferred to the first ligand displacement precursor solution, then the n-octane solution was poured out, and then the n-octane solvent was mixed and washed with the first ligand displacement precursor solution three times. Then adding toluene to the first ligand displacement precursor solution for precipitation, and then vacuum drying the obtained precipitate to obtain CdSe quantum dots having cadmium iodide and cadmium bromide as ligands.

### Quantum Dot Preparation Example 2

It differs from Example 1 in step 2. A second ligand displacement precursor solution was prepared by dissolving 192.3 mg of cadmium iodide and 25.6 mg of ammonium acetate in 5 mL of methylformamide. Then, 5 mL of the CdSe quantum dot n-octane solution was uniformly mixed with the second ligand displacement precursor solution until all quantum dots were transferred to the second ligand replacement precursor solution, then the n-octane solution was poured out, and then the n-octane solvent was mixed and washed with the second ligand displacement precursor solution for three times. Then adding toluene to the second ligand displacement precursor solution for precipitation, and then vacuum drying the obtained precipitate to obtain CdSe quantum dots with cadmium iodide as ligands.

### Quantum Dot Preparation Example 3

It differs from Example 1 in step 2. A third ligand displacement precursor solution was prepared by dissolving 30.2 mg of cadmium iodide and 25.6 mg of ammonium acetate in 5 mL of methylformamide. Then, 5 mL of the above CdSe quantum dot n-octane solution was uniformly mixed with the third ligand replacement precursor solution until all quantum dots were transferred to the third ligand displacement precursor solution, then the n-octane solution was poured out, and then the n-octane solvent was mixed and washed with the third ligand displacement precursor solution for three times. Then adding toluene to the third ligand displacement precursor solution for precipitation, and then vacuum drying the obtained precipitate to obtain CdSe quantum dots with cadmium bromide as ligands.

### Quantum Dot Preparation Example 4

It differs from Example 3 in that the quantum dots are CdZnS.

### Quantum Dot Preparation Example 5

This is different from Example 3 in that the quantum dots had a core-shell structure, wherein a core material of the core-shell structure was CdTe, and a shell material of the core-shell structure was ZnTe.

### Quantum Dot Preparation Example 6

An appropriate amount of CdSe quantum dots having cadmium iodide as ligands was dispersed in an n-butylamine solvent to obtain a first quantum dot solution having a concentration of 10 mg/mL.

0.1 mL of 0.1 mol/L 2-aminoethanethiol-DMF solution was slowly added dropwise to 20 mL of the first quantum dot solution, and stirred for 10 minutes to mix thoroughly to obtain a mixed solution, and then the mixed solution was poured into toluene to precipitate to obtain a precipitate, which was washed and purified by DMF-toluene and dried in a vacuum drying oven to obtain CdSe quantum dot powder having 2-aminoethanethiol as ligands.

### Quantum Dot Preparation Example 7

This differs from Example 6 in that the 2-aminoethanethiol-DMF solution was replaced with the 2-mercaptoethanol-DMF solution.

### Quantum Dot Preparation Example 8

This differs from Example 6 in that the 2-aminoethanethiol-DMF solution was replaced with the 4-hydroxythiophenol-DMF solution.

### Quantum Dot Preparation Example 9

This differs from Example 6 in that the 2-aminoethanethiol-DMF solution was replaced with the 4-hydroxythiophene-DMF solution.

### Quantum Dot Preparation Example 10

This differs from Example 6 in that the 2-aminoethanethiol-DMF solution was replaced with the oxalic acid-DMF solution.

### Quantum Dot Preparation Example 11

It differs from Example 6 in that the CdSe quantum was replaced with CdZnS.

### Quantum Dot Preparation Example 12

This is different from Example 6 in that CdSe quantum was replaced with quantum dots of a core-shell structure in which the core material of the core-shell structure is InP and the shell material of the core-shell structure is ZnS.

### Composite Material Preparation Example 1

An appropriate amount of CdSe quantum dots with cadmium iodide as ligands was dispersed in n-butylamine solvent to obtain a first quantum dot solution with a concentration of 10 mg/mL. An appropriate amount of CdSe quantum dots having 2-aminoethanethiol as ligands was dispersed in n-butylamine solvent to obtain a second quantum dot solution with a concentration of 10 mg/mL.

1 mL of the first quantum dot solution and 1 mL of the second quantum dot solution were uniformly mixed to obtain a quantum dot mixed solution, and the solvent in the quantum dot mixed solution was removed to obtain a composite material sample 1.

### Composite Material Preparation Example 2

It is different from Composite Preparation Material Example 1 in that 1 ml of the first quantum dot solution and 5 ml of the second quantum dot solution were uniformly mixed to obtain a quantum dot mixed solution, and the solvent in the quantum dot mixed solution was removed to obtain a composite material sample 2.

### Composite Material Preparation Example 3

It is different from Composite Material Preparation Example 1 in that 1 ml of the first quantum dot solution and 10 ml of the second quantum dot solution were uniformly mixed to obtain a quantum dot mixed solution, and the solvent in the quantum dot mixed solution was removed to obtain a composite material sample 3.

### Composite Material Preparation Example 4

It is different from Composite Material Preparation Example 1 in that 5 ml of the first quantum dot solution and 1 ml of the second quantum dot solution were uniformly mixed to obtain a quantum dot mixed solution, and the solvent in the quantum dot mixed solution was removed to obtain a composite material sample 4.

### Composite Material Preparation Example 5

It is different from Composite Material Preparation Example 1 in that 10 ml of the first quantum dot solution and 1 ml of the second quantum dot solution were uniformly mixed to obtain a quantum dot mixed solution, and the solvent in the quantum dot mixed solution was removed to obtain a composite material sample 5.

### Composite Material Preparation Example 6

This is different from Composite Material Preparation Example 1 in that the CdSe quantum dots in the first quantum dot solution and the CdSe quantum dots in the second quantum dot solution are both replaced with CdZnS quantum dots.

### Composite Material Preparation Example 7

It differs from Composite Material Preparation Example 1 in that the ligand of the CdSe quantum dots in the first quantum dot solution is replaced with cadmium bromide.

### Composite Material Preparation Example 8

This is different from Composite Material Preparation Example 1 in that the ligands of the CdSe quantum dots in the first quantum dot solution were cadmium bromide and cadmium iodide, wherein the molar ratio of cadmium bromide to cadmium iodide is 3:2.

### Composite Material Preparation Example 9

This is different from Composite Material Preparation Example 1 in that the ligands of the CdSe quantum dots in the second quantum dot solution were 2-mercaptoethanol.

### Composite Material Preparation Example 10

This is different from Composite Material Preparation Example 1 in that the ligands of the CdSe quantum dots in the second quantum dot solution were 4-hydroxythiophenol.

### Composite Material Preparation Example 11

This is different from Composite Material Preparation Example 1 in that the ligands of the CdSe quantum dots in the second quantum dot solution were 4-hydroxythiophene.

### Composite Material Preparation Example 12

This is different from Composite Material Preparation Example 1 in that the ligands of the CdSe quantum dots in the second quantum dot solution were oxalic acid.

### Composite Material Preparation Example 13

It is different from Composite Material Preparation Example 1 in that the CdSe quantum dots in the first quantum dot solution and the second quantum dot solution were replaced with quantum dots of a core-shell structure, wherein the core material of the core-shell structure was CdTe, and the shell material of the core-shell structure was ZnTe.

| | fluorescence quantum yield |
|---|---|
| Project Name | (%) |
| Composite Material Preparation Example 1 | 6.3 |
| Composite Material Preparation Example 2 | 12.1 |
| Composite Material Preparation Example 3 | 15.2 |
| Composite Material Preparation Example 4 | 7.3 |
| Composite Material Preparation Example 5 | 8.2 |
| Composite Material Preparation Example 6 | 6.1 |
| Composite Material Preparation Example 7 | 4.2 |
| Composite Material Preparation Example 8 | 5.4 |
| Composite Material Preparation Example 9 | 6.1 |
| Composite Material Preparation Example 10 | 6.1 |
| Composite Material Preparation Example 11 | 5.9 |
| Composite Material Preparation Example 12 | 5.8 |
| Composite Material Preparation Example 13 | 5.8 |

### Device Example 1

Step 1: A first electrode ITO was prepared on a glass substrate with a thickness of 110 nm.
Step 2: A hole injection layer was prepared on the first electrode ITO, the material was PEDOT:PSS, and the thickness was 100 nm.
Step 3: A hole transport layer was prepared on the hole injection layer, the material was TFB, and the thickness was 70 nm.
Step 4: A quantum dot light-emitting layer was prepared on the hole transport layer with a thickness of 20 nm. Wherein the quantum dot light-emitting layer includes a compound mixture of first quantum dots and second quantum dots, and the molar ratio of the first quantum dots to the second quantum dots is 1:1. A first quantum dot is a CdSe quantum dot (cadmium iodide and cadmium bromide as ligands). A second quantum dot is a CdSe quantum dot (2-aminoethanethiol as ligand).
Step 5: An electron transport layer ZnO was prepared on the quantum dot light-emitting layer with a thickness of 70 nm.
Step 6: A second electrode was prepared on the electron transport layer, the second electrode is silver and has a thickness of 60 nm.

### Device Example 2

This differs from Device Example 1 in that the molar ratio of the first quantum dot and the second quantum dot in step 4 is 1:2.5.

### Device Example 3

This differs from Device Example 1 in that the molar ratio of the first quantum dot and the second quantum dot in step 4 is 2:1.

### Device Example 4

This differs from Device Example 1 in that the molar ratio of the first quantum dot and the second quantum dot in step 4 is 1:4.

### Device Example 5

This differs from Device Example 1 in that the molar ratio of the first quantum dot and the second quantum dot in step 4 is 3:1.

### Device Example 6

It differs from Device Example 1 in that:
Step 3 A hole transport layer was prepared on the hole injection layer, the material was PVK (poly (9-vinylcarbazole)), and the thickness was 80 nm.
Step 4: preparing a quantum dot light-emitting layer on the hole transport layer with a thickness of 20 nm; Wherein the quantum dot light-emitting layer includes a compounded first quantum dot and a second quantum dot, and the molar ratio of the first quantum dot and the second quantum dot is 5:1. The first quantum dot is a CdSe quantum dot (cadmium iodide and cadmium bromide as ligands). The second quantum dot is a CdSe quantum dot (2-aminoethanethiol as ligand).
Step 5: Preparing an electron transport layer (magnesium doped ZnO, magnesium doping ratio 10%) on the quantum dot light-emitting layer with a thickness of 80 nm.

### Device Example 7

This differs from Device Example 6 in that the molar ratio of the first quantum dots to the second quantum dots in step 4 was 20:1.

### Device Example 8

This differs from Device Example 6 in that the molar ratio of the first quantum dots to the second quantum dots in step 4 was 3.5:1.

### Device Example 9

This differs from Device Example 6 in that the molar ratio of the first quantum dots to the second quantum dots in step 4 was 25:1.

### Device Example 10

This differs from Device Example 6 in that the molar ratio of the first quantum dots to the second quantum dots in step 4 was 2:1.

### Device Comparative Example 1

This differs from Device Example 1 in step 4 as follow.
Step 4: A quantum dot light-emitting layer was prepared on the hole transport layer with a thickness of 20 nm; Among them, the material of the quantum dot light-emitting layer was CdSe quantum dots (with myristic acid as ligands).

### Device Comparative Example 2

This differs from Device Example 1 in step 4 as follow.
Step 4: A quantum dot light-emitting layer was prepared on the hole transport layer with a thickness of 20 nm; Among them, the material of the quantum dot light-emitting layer was CdSe quantum dots (with 2-aminoethanethiol as ligands).

### Device Comparative Example 3

This differs from Device Example 1 in step 4 as follow.
Step 4: A quantum dot light-emitting layer was prepared on the hole transport layer with a thickness of 20 nm; Among them, the material of the quantum dot light-emitting layer was CdSe quantum dots (with cadmium iodide and cadmium bromide as ligands).

### Device Comparative Example 4

This differs from Device Example 6 in the following steps.

A quantum dot light-emitting layer was prepared on the hole transport layer with a thickness of 20 nm; Among them, the material of the quantum dot light-emitting layer was CdSe quantum dots (with myristic acid was prepared).

### Device Comparative Example 5

This differs from Device Example 1 in step 4 as follow.
Step 4: A quantum dot light-emitting layer was prepared on the hole transport layer with a thickness of 20 nm; Among them, the material of the quantum dot light-emitting layer was CdSe quantum dots (with 2-aminoethanethiol was prepared).

### Device Comparative Example 6

This differs from Device Example 1 in step 4 as follow.
Step 4: A quantum dot light-emitting layer was prepared on the hole transport layer with a thickness of 20 nm; Among them, the material of the quantum dot light-emitting layer was CdSe quantum dots (cadmium iodide and cadmium bromide were ligands).

The performance of the light-emitting devices obtained in Device Examples 1-10 and Device Comparative Examples 1-6 was tested, and the test results are shown in Tables 1 and 2 below.

TABLE 1

| | peak | | | |
|---|---|---|---|---|
| | wavelength | FWHM | EQEₘₐₓ | T95@1000 nit |
| Project Name | (nm) | (nm) | (%) | (hours) |
| Device Example 1 | 587 | 20 | 22 | 4413 |
| Device Example 2 | 586 | 21 | 17 | 3532 |
| Device Example 3 | 586 | 23 | 16 | 3397 |
| Device Example 4 | 586 | 21 | 17 | 2432 |
| Device Example 5 | 586 | 23 | 16 | 2221 |
| Device | 586 | 23 | 12 | 2250 |
| Comparative | | | | |
| Example 1 | | | | |
| Device | 586 | 21 | 15 | 219 |
| Comparative | | | | |
| Example 2 | | | | |
| Device | 586 | 22 | 18 | 2182 |
| Comparative | | | | |
| Example 3 | | | | |

TABLE 2

| | peak | | | |
|---|---|---|---|---|
| | wavelength | FWHM | EQEₘₐₓ | T95@1000 nit |
| Project Name | (nm) | (nm) | (%) | (hours) |
| Device Example 6 | 587 | 23 | 20 | 3825 |
| Device Example 7 | 587 | 23 | 20 | 3226 |
| Device Example 8 | 587 | 23 | 20 | 3017 |
| Device Example 9 | 586 | 26 | 15 | 2347 |
| Device Example 10 | 587 | 25 | 13 | 2297 |
| Device | 586 | 24 | 16 | 1955 |
| Comparative | | | | |
| Example 4 | | | | |
| Device | 586 | 27 | 15 | 2032 |
| Comparative | | | | |
| Example 5 | | | | |
| Device | 586 | 25 | 14 | 2282 |
| Comparative | | | | |
| Example 6 | | | | |

What is claimed is:

1. A composite material comprising:
first quantum dots, each of the first quantum dots having N-type ligands thereon; and
second quantum dots, each of the second quantum dots having P-type ligands thereon.

2. The composite material according to claim 1, wherein each of the first quantum dots comprises a metal element M, and each of the N-type ligands is selected from a halide of the metal element M.

3. The composite material according to claim 2, wherein each of the N-type ligands comprises one or more of zinc halide, cadmium halide, mercury halide, lead halide, tin halide, copper halide, silver halide, gallium halide and indium halide.

4. The composite material according to claim 2, wherein each of the N-type ligands comprises one or more of zinc fluoride, zinc chloride, zinc bromide, zinc iodide, cadmium fluoride, cadmium chloride, cadmium bromide and cadmium iodide.

5. The composite material according to claim 1, wherein each of the P-type ligands is selected from any one or more of the compounds represented by the following formula I, 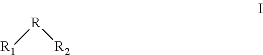
wherein R₁ and R₂ are each independently selected from one of —H, —SH, —COOH, —NH₂, —OH, —NHR₃, —NR₄R₅, —PO₃H₂, —PO₃HR₆, —PO₃R₇R₈, —SO₃H and —SO₃R₉, but not all are H;
R is selected from one of a C₁-C₃₀ divalent aliphatic hydrocarbon group, a C₆-C₃₀ arylene group and a C₃-C₃₀ divalent heteroaryl group having heteroatoms selected from O, S, N and P;
R₃, R₄, R₅, R₆, R₇, R₈ and R₉ are selected from C₁-C₆ hydrocarbyl groups.

6. The composite material according to claim 5, wherein R in each of the P-type ligands is selected from one of a C₃-C₁₅ divalent aliphatic hydrocarbon group, a C₆-C₁₈ arylene group and a C₆-C₁₈ divalent heteroaryl group.

7. The composite material according to claim 5, wherein each of the P-type ligands comprises one or more of propylene glycol, butanediol, pentanediol, hexanediol, 2-mercaptoethanol, 2-mercaptophenol, 3-mercaptophenol, 4-hydroxythiophenol, 4-hydroxythiophene, 2-aminoethanethiol, 2-aminothiophenol, 3-aminothiophenol, 4-aminothiophenol, oxalic acid, malonic acid, succinic acid, adipic acid, and maleic acid.

8. The composite material according to claim 1, wherein a molar ratio of the first quantum dots to the second quantum dots ranges from 0.25 to 25.

9. The composite material according to claim 1, wherein an average particle size of the first quantum dots ranges from 7 nm to 12 nm.

10. The composite material according to claim 1, wherein an average particle size of the second quantum dots ranges from 7 nm to 12 nm.

11. The composite material according to claim 1, wherein the first quantum dots and the second quantum dots are independently selected from one or more of a single structure quantum dot, a core-shell structure quantum dot, and a perovskite-type semiconductor material, wherein a material of the single structure quantum dot, a core material of the core-shell structure quantum dot and a shell material of the core-shell structure quantum dot are respectively selected from at least one of a Group II-VI compound, a Group IV-VI compound, a Group III-V compound, and a Group I-III-VI compound, the Group II-VI compound is selected from one or more of CdS, CdSe, CdTe, ZnS, ZnSe, ZnTe, ZnO, CdSeS, ZnSeS, ZnSeTe, ZnSTe, and CdZnSeS, the Group III-V compound is selected from GaN, GaP, GaAs, GaSb, AlN, AIP, AlAs, AlSb, InN, InP, GaNP, AlNP, AlNAs, AlNSb, AlPAs, AlPSb, InNP, GaAlNP, GaAlNAs, GaInNP, and InAlNP, the Group I-III-VI compound is selected from one or more of CuInS₂, CuInSe₂, and AgInS₂.

12. The composite material according to claim 1, wherein a material of each of the first quantum dots and a material of each of the second quantum dots are the same.

13. A method of preparing a composite material, comprising:
providing first quantum dots and second quantum dots, wherein each of the first quantum dots has N-type ligands thereon, and each of the second quantum dots has P-type ligands thereon;
mixing a first quantum dot solution having the N-type ligands and a second quantum dot solution having the P-type ligands according to a preset ratio to obtain a quantum dot mixed solution, and removing a solvent in the quantum dot mixed solution to obtain the composite material.

14. The method according to claim 13, wherein the step of providing first quantum dots and second quantum dots comprises:
providing an initial quantum dot solution, wherein the initial quantum dot solution comprises quantum dots and initial ligands bonded to the surface of the quantum dots;
dropwise adding a solution having the N-type ligands to the initial quantum dot solution to obtain a first ligand replacement precursor solution, and performing ligand exchange between the N-type ligands and the initial ligands in the first ligand replacement precursor solution by a solution ligand exchange method to obtain the first quantum dots, wherein each of the first quantum dots has the N-type ligands thereon; and,
dropwise adding a solution having the P-type ligands to the first quantum dot solution to obtain a second ligand replacement precursor solution, and performing ligand exchange between the P-type ligands and the N-type ligands in the second ligand replacement precursor solution by the solution ligand exchange method to obtain the second quantum dots, wherein each of the second quantum dots has the P-type ligands thereon.

15. The method according to claim 13, wherein each of the P-type ligands is selected from any one or more of the compounds represented by the following formula I, 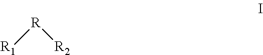
wherein R₁ and R₂ are each independently selected from one of —H, —SH, —COOH, —NH₂, —OH, —NHR₃, —NR₄R₅, —PO₃H₂, —PO₃HR₆, —PO₃R₇R₈, —SO₃H and —SO₃R₉, but not all are H; R is selected from one of a C₁-C₃₀ divalent aliphatic hydrocarbon group, a C₆-C₃₀ arylene group and a C₃-C₃₀ divalent heteroaryl group having heteroatoms selected from O, S, N and P; R₃, R₄, R₅, R₆, R₇, R₈ and R₉ are selected from C₁-C₆ hydrocarbyl groups.

16. The method according to claim 13, wherein each of the first quantum dots comprises a metal element M, and the N-type ligand is selected from a halide of the metal element M.

17. A light-emitting device comprising a light-emitting layer, wherein the light-emitting layer is made of a composite material comprising first quantum dots and second quantum dots;
each of the first quantum dots have N-type ligands thereon, and each of the second quantum dots have P-type ligands thereon.

18. The light-emitting device according to claim 17, wherein each of the first quantum dots comprises a metal element M, and each of the N-type ligands is selected from a halide of the metal element M;
each of the P-type ligands is selected from any one or more of the compounds represented by the following formula I, 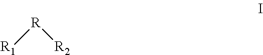
wherein R₁ and R₂ are each independently selected from one of —H, —SH, —COOH, —NH₂, —OH, —NHR₃, —NR₄R₅, —PO₃H₂, —PO₃HR₆, —PO₃R₇R₈, —SO₃H and —SO₃R₉, but not all are H; R is selected from one of a C₁-C₃₀ divalent aliphatic hydrocarbon group, a C₆-C₃₀ arylene group and a C₃-C₃₀ divalent heteroaryl group having heteroatoms selected from O, S, N and P; R₃, R₄, R₅, R₆, R₇, R₈ and R₉ are selected from C₁-C₆ hydrocarbyl groups.

19. The light-emitting device according to claim 18, wherein each of the N-type ligands comprises one or more of zinc fluoride, zinc chloride, zinc bromide, zinc iodide, cadmium fluoride, cadmium chloride, cadmium bromide and cadmium iodide; each of the P-type ligands comprises one or more of propylene glycol, butanediol, pentanediol, hexanediol, 2-mercaptoethanol, 2-mercaptophenol, 4-hydroxythiophene, 2-aminoethanethiol, 3-mercaptophenol, 4-hydroxythiophenol, 2-aminothiophenol, 3-aminothiophenol, 4-aminothiophenol, oxalic acid, malonic acid, succinic acid, adipic acid, maleic acid.

20. The light-emitting device according to claim 17, wherein a molar ratio of the first quantum dots to the second quantum dots ranges from 0.25 to 25.
